(19) United States
(12) Patent Application Publication
(10) Pub. No.: US 2023/0389246 A1
(43) Pub. Date: Nov. 30, 2023

(54) CASE

(71) Applicant: Murata Manufacturing Co., Ltd., Nagaokakyo-shi (JP)

(72) Inventor: Kiyoyuki NAKAGAWA, Nagaokakyo-shi (JP)

(21) Appl. No.: 18/231,857

(22) Filed: Aug. 9, 2023

Related U.S. Application Data
(63) Continuation of application No. PCT/JP2022/007007, filed on Feb. 21, 2022.

(30) Foreign Application Priority Data
Feb. 26, 2021 (JP) 2021-030243

(51) Int. Cl. H05K 13/00

(52) U.S. Cl. CPC H05K 13/0084

(57) ABSTRACT

A case to be set to a feeder to supply electronic components to a supply target includes a case body including a storage space to accommodate electronic components, a transport section integrally joined to the case body and including a transport path to transport the electronic components to a supply target, a discharge port through which the electronic components in the transport path are discharged, and a communication port to communicate between the storage space and the transport path to enable the electronic components to move from the storage space to the transport path.

### CROSS REFERENCE TO RELATED APPLICATIONS

This application claims the benefit of priority to Japanese Patent Application No. 2021-030243 filed on Feb. 26, 2021 and is a Continuation Application of PCT Application No. PCT/JP2022/007007 filed on Feb. 21, 2022. The entire contents of each application are hereby incorporated herein by reference.

### BACKGROUND OF THE INVENTION

### 1. Field of the Invention

The present invention relates to a case to accommodate electronic components such as chip components and to supply the accommodated components to a predetermined supply target.

### 2. Description of the Related Art

When mounting electronic components on a board, a mounting device is used which mounts each of the electronic components at a predetermined position on the board.

It is necessary to supply the electronic components individually to such a mounting device.

For example, Japanese Unexamined Patent Application, Publication No. 2009-295618 discloses a case in which electronic components in a loose state are collectively accommodated, and the electronic components drop onto a feeder by their own weight from a take-out port at a bottom portion.

The electronic components are individually supplied to the mounting device by the feeder.

In such a case as disclosed in Japanese Unexamined Patent Application, Publication No. 2009-295618, components transferred from the case may remain in the feeder, and components newly supplied from the case may be mixed with the remaining components.

Such mixing of components may cause a failure in that correct mounting of components becomes impossible, and management of components in subsequent steps becomes difficult.

### SUMMARY OF THE INVENTION

Preferred embodiments of the present invention provide cases that each reduce or prevent mixing of components on a case side and components on a supply destination side in a process of supplying components from a case to a component supply destination.

A case according to a preferred embodiment of the present invention is to be set to a feeder to supply a component to a supply target, wherein the case includes a case body including a housing space that houses a plurality of components, a transport section including a transport path that is integrally joined to the case body and transports the plurality of components to the supply target and a discharge port that discharges the plurality of components from the transport path, and a communication port that communicates the housing space and the transport path with each other and enables the plurality of components to move from the housing space to the transport path.

According to preferred embodiments of the present invention, cases are provided that each reduce or prevent mixing of components on a case side and components on a supply destination side in a process of supplying components from a case to a component supply destination.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a side view showing the interior of a case set to a feeder according to a preferred embodiment of the present invention.

FIG. 2 is a bottom view of a case according to a preferred embodiment of the present invention.

FIG. 3 is a cross-sectional view taken along the line III-III in FIG. 1.

FIG. 4 is a side view of the interior of a case according to a preferred embodiment of the present invention set to the feeder, showing a state in which electronic components are supplied from the case to the mounting device.

FIG. 5 is a cross-sectional view taken along the line V-V in FIG. 4.

### DETAILED DESCRIPTION OF THE PREFERRED EMBODIMENTS

Hereinafter, preferred embodiments of the present invention will be described with reference to the drawings.

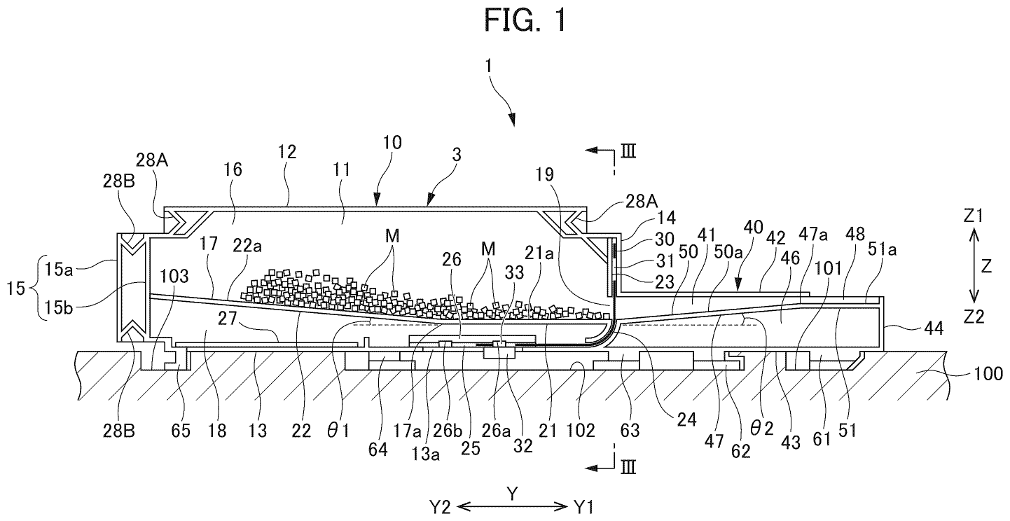

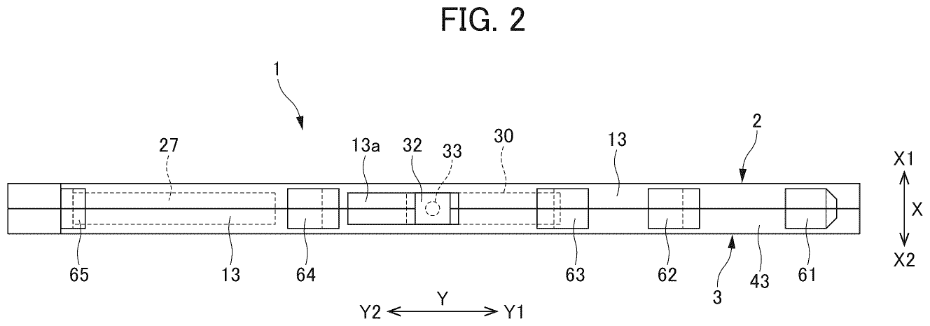

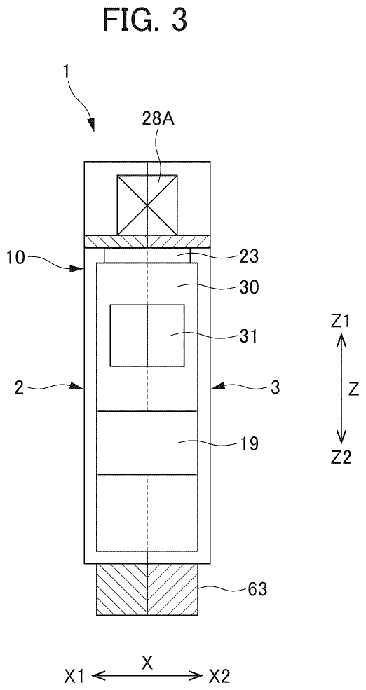

FIG. 1 is a side view showing the interior of a case 1 according to a preferred embodiment of the present invention. FIG. 2 is a bottom view of the case 1. FIG. 3 is a cross-sectional view taken along the line III-III of FIG. 1.

As shown in FIG. 1, the case 1 houses therein a plurality of electronic components (shown in FIG. 1) M as components in a loose state.

The case 1 housing the plurality of electronic components M is detachably set to the feeder 100.

The feeder 100 of the present preferred embodiment is a device that conveys the electronic components M housed in the case 1 by vibration, discharges the electronic components M from the case 1, and supplies the electronic components M to a mounting device (not shown).

Each of the electronic components M of the present preferred embodiment is, for example, a small rectangular parallelepiped electronic component having a length of about 1.2 mm or less in the longitudinal direction.

Examples of such electronic components include capacitors and inductors. However, the present preferred embodiment is not limited thereto.

Arrows X, Y, and Z shown in FIGS. 1, 2, and 3 respectively indicate the lateral (or left-right) direction, the longitudinal (or front-rear) direction, and the vertical (or up-down) direction of the case 1 when the case 1 is set to the feeder 100.

Furthermore, the left side in the lateral direction X is denoted by X1, the right side is denoted by X2, the front side in the longitudinal direction Y is denoted by Y1, the rear side is denoted by Y2, the upper side in the vertical direction Z is denoted by Z1, and the lower side is denoted by Z2.

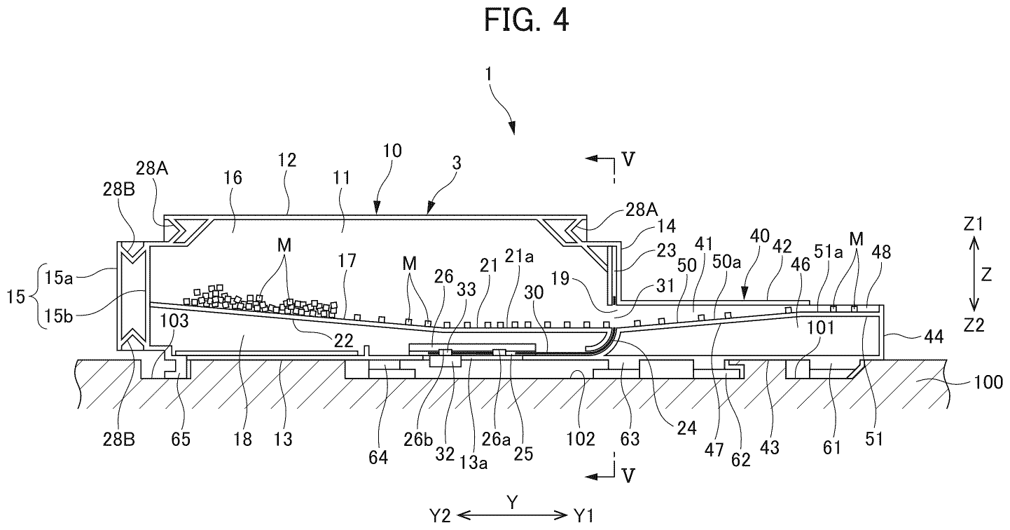

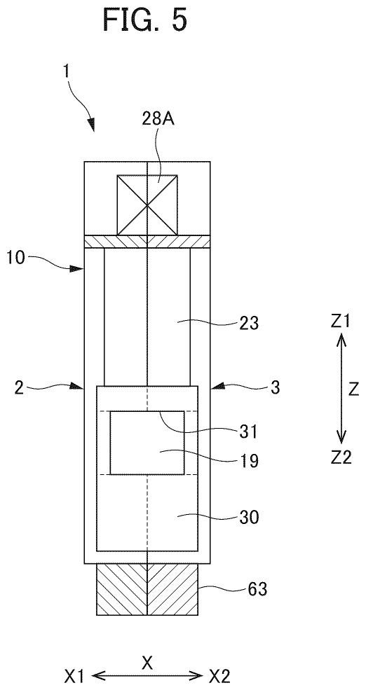

Also in FIGS. 4 and 5, the lateral direction X, the longitudinal direction Y, and the vertical direction Z are similarly applied.

The lateral direction, the longitudinal direction, and the vertical direction in the following description are based on the directions indicated by the arrows described above.

As shown in FIGS. 2 and 3, the case 1 is configured such that a first member 2 and a second member 3 are combined and joined to each other to be bilaterally symmetrical.

FIG. 1 shows a state without the first member 2 on the left side, and shows the interior of the second member 3 on the right side.

The case 1 has a flat box shape that is long in the longitudinal direction and thin in the lateral direction.

In the following description, except where necessary, the first member 2 and the second member 3 are not individually described, and a configuration in which the first member 2 and the second member 3 are joined to each other will be described.

The material of the case 1 has a surface resistivity of, for example, about 10E8 Ω/mm² to about 10E11 Ω/mm², and is preferably a thermoplastic resin, for example.

The case 1 of the present preferred embodiment is set to the feeder 100, and is a case to supply the electronic components M to the mounting device defining and functioning as a supply target.

As shown in FIG. 1, the case 1 includes a case body 10, a transport section 40, a communication port 19 provided between the case body 10 and the transport section 40, and a shutter 30.

The case body 10 includes a housing space 11 to house the plurality of electronic components M in a loose state.

The case body 10 includes a top plate portion 12 and a bottom plate portion 13 which extend in the longitudinal direction, a front wall portion 14 and a rear wall portion 15 which extend in the vertical direction, a pair of left and right lateral wall portions 16, and a partition plate portion 17 which partitions the interior of the case body 10 vertically.

The rear wall portion 15 includes an outer rear wall portion 15a providing an outer surface and an inner rear wall portion 15b in front of the outer rear wall portion.

The communication port 19 is provided at a lower portion of the front wall portion 14.

The communication port 19 is a rectangular or substantially rectangular opening.

The communication port 19 is not limited to a rectangular or substantially rectangular shape, and may be, for example, an opening having a circular or substantially circular shape, an elliptical or substantially elliptical shape, or the like.

The communication port 19 is opened and closed by the shutter 30 described later.

The partition plate portion 17 extends between the left and right lateral wall portions 16 and between the front wall portion 14 and the inner rear wall portion 15b.

The partition plate portion 17 is provided below the center of the interior of the case body 10 in the vertical direction.

In the case body 10, the upper side of the partition plate portion 17 defines and functions as a housing space 11, and the lower side of the partition plate portion 17 defines and functions as a lower space 18.

The partition plate portion 17 includes a first horizontal portion 21 on the front side and a first sloped portion 22 on the rear side at a position of about ⅓ from the front end toward the rear side in the longitudinal direction (indicated by 17a in FIG. 1).

The upper surface of the first horizontal portion 21 is a first horizontal surface 21a which is horizontal or substantially horizontal.

The first sloped portion 22 is sloped at a downward gradient toward the communication port 19, and an upper surface of the first sloped portion 22 is a first sloped surface 22a sloped at a downward gradient toward the communication port 19.

In the present preferred embodiment, the slope angle θ1 of the first sloped surface 22a is, for example, about 10° with respect to the horizontal direction when the case 1 is set to the feeder 100.

The slope angle θ1 of the first sloped surface 22a is, for example, preferably about 3° or more and about 15° or less, and more preferably about 3° or more and about 5° or less.

The shutter 30 opens and closes the communication port 19.

The shutter 30 continuously extends from the bottom plate portion 13 to the front wall portion 14.

The shutter 30 is an elongated strip-shaped film.

The shutter 30 is made of a bendable flexible material having a certain degree of rigidity such as, for example, PET (Polyethylene terephthalate).

The width of the shutter 30 is slightly larger than the width of the communication port 19, and has a width capable of covering the communication port 19 without any gap.

As shown in FIGS. 1 and 3, an opening 31 having the same or substantially the same shape as the communication port 19 is provided in the front end portion of the shutter 30.

The case body 10 includes an upper guide 23 provided above the communication port 19, a curved guide 24 provided below the communication port 19, and a bottom guide 25 provided above the bottom plate portion 13.

The shutter 30 is slidably inserted across the upper guide 23, the curved guide 24, and the bottom guide 25.

Each of the upper guide 23, the curved guide 24, and the bottom guide 25 is a slit-shaped passage that slidably holds the shutter 30 while maintaining the surface direction of the shutter 30 along the lateral direction.

The shutter 30 slides in the longitudinal direction from the bottom guide 25 to the curved guide 24, and by passing through the curved guide 24, the shutter 30 is bent upward at an angle of approximately 90°, and is converted to a posture extending in the vertical direction.

The shutter 30 slides in the vertical direction between the curved guide 24 and the upper guide 23.

A slider 32 including a plate piece to open and close the shutter 30 is attached to the rear end of the shutter 30.

The slider 32 is attached integrally with the shutter 30 and projects to the lower surface side of the shutter 30.

As shown in FIGS. 1 and 2, the bottom plate portion 13 is provided with a hole 13a that allows the slider 32 to project downward and allows the slider 32 to move in the longitudinal direction.

When the slider 32 moves in the longitudinal direction, the shutter 30 slides along the upper guide 23, the curved guide 24, and the bottom guide 25.

In the range in which the shutter 30 slides, when the opening 31 coincides with the communication port 19, the communication port 19 opens, and when the opening 31 is provided in the upper guide above the communication port 19, the communication port 19 is closed by the shutter 30.

The slider 32 includes a stopper 33 to position the slide position of the shutter 30 at two positions, i.e., a position where the opening 31 of the shutter 30 coincides with the communication port 19 and a position where the shutter 30 closes the communication port 19.

The stopper 33 includes a protruding portion which protrudes from the upper surface of the slider 32.

As shown in FIG. 1, a plate 26 providing the bottom guide is provided above the bottom plate portion 13 in the lower space 18, and a front recessed portion 26a and a rear recessed portion 26b are provided in a pair at the front side and the rear side on a lower surface of the plate 26.

The stopper 33 engages with one of the front recessed portion 26a and the rear recessed portion 26b.

When the slider 32 moves forward and the stopper 33 engages with the front recessed portion 26a, the opening 31 is positioned at the front wall portion 14 above the communication port 19, and the communication port 19 is closed by the shutter 30, as shown in FIGS. 1 and 3.

When the slider 32 moves rearward and the stopper 33 engages with the rear recessed portion 26b, the opening 31 coincides with the communication port 19, and the communication port 19 is opened as shown in FIGS. 4 and 5.

The electronic components M housed in the housing space 11 pass through the open communication port 19 and move to the transport section 40.

The slider 32 may be manually slid, or may be driven using a device such as an actuator, for example.

As shown in FIG. 1, a band-shaped RFID tag 27 elongated in the longitudinal direction is provided at a rear portion of the lower space 18.

The RFID tag 27 is configured in, for example, a shielded state and is attached to the upper surface of the bottom plate portion 13.

The RFID tag 27 has a publicly known configuration including a transmission/reception unit, memory, an antenna, and the like.

A reader/writer (not shown) to read and write information from and to the RFID tag 27 is provided in the feeder 100.

The case body 10 includes upper grip portions 28A and rear grip portions 28B.

The upper grip portions 28A are a pair of front and rear depressions provided at both front and rear ends of the upper side of the case body 10.

The rear grip portions 28B are a pair of upper and lower depressions provided at both upper and lower ends of the rear side of the case body 10.

Each of the upper grip portions 28A and the rear grip portions 28B is gripped by a robot hand, for example, when the case 1 is carried by the robot hand.

The transport section 40 has a rectangular or substantially rectangular parallelepiped box shape extending forward from the case body 10.

Similarly to the case body 10, the transport section 40 is configured by combining the first member 2 and the second member 3 and has the same or substantially the same thickness in the lateral direction as that of the case body 10.

The length of the transport section 40 in the longitudinal direction Y may be shorter than the length of the case body 10 so as to avoid interference with peripheral devices. The transport section 40 includes a transport space 41 to transport forward the electronic components M, which pass through the communication port 19 and are transferred from the case body 10.

The transport space 41 communicates with the housing space 11 of the case body 10 via the communication port 19.

The transport section 40 includes a top plate section 42 and a bottom plate section 43 extending in the longitudinal direction, a front wall section 44 extending in the vertical direction, a pair of left and right lateral wall sections 46, and a transport path 47 in the transport section 40.

The top plate section 42 extends forward from the upper end position of the communication port 19.

The bottom plate section 43 is located at the same or substantially the same vertical position as the bottom plate portion 13 of the case body 10, and continuously extends forward in a state of extending forward from the bottom plate portion 13.

The front wall section 44 rises upward from the front end of the bottom plate section 43.

The front end of the top plate section 42 does not extend to the front wall section 44, and a discharge port 48 opening upward is provided between the front end of the top plate section 42 and the upper end of the front wall section 44.

The transport path 47 includes a plate-shaped member, and is provided so as to be continuous with the first horizontal portion 21 of the partition plate portion 17 of the case body 10.

The transport path 47 extends between the left and right lateral wall sections 46 and between the rear end of the transport section 40 and the front wall section 44.

The transport path 47 includes a second horizontal portion 51 on the front side and a second sloped portion 50 on the rear side at a position of about ¼ from the front end toward the rear side in the longitudinal direction (indicated by 47a in FIG. 1).

The upper surface of the second horizontal portion 51 is a second horizontal surface 51a, and the discharge port 48 is provided above the second horizontal surface 51a.

The upper surface of the second sloped portion 50 is a second sloped surface 50a sloped at an upward gradient toward the discharge port 48 at the front.

In the present preferred embodiment, the slope angle θ2 of the second sloped surface 50a is, for example, about 10° with respect to the horizontal direction when the case 1 is set to the feeder 100.

The slope angle θ2 of the second sloped surface 50a is, for example, preferably about 3° or more and about 10° or less.

The electronic components M pass through the communication port 19 from the first horizontal surface 21a of the case body 10 and moves onto the second sloped surface 50a of the transport path 47.

θ2 is preferably an angle at which the electronic components M tend to move up, and may be equal to θ1, for example.

Angles θ1 and θ2 are appropriately adjusted according to a vibration condition described later.

As shown in FIG. 1, the case 1 includes a plurality of claw portions on the bottom surface to detachably set the case 1 in the feeder 100.

In the present preferred embodiment, a first claw portion 61, a second claw portion 62, a third claw portion 63, a fourth claw portion 64, and a fifth claw portion 65 are provided on the bottom surface at intervals in the longitudinal direction.

The first claw portion 61, the second claw portion 62, and the third claw portion 63 are provided adjacent to the transport section 40, and the fourth claw portion 64 and the fifth claw portion 65 are provided adjacent to the case body 10.

The first claw portion 61 engages with a first recessed portion 101 on the upper surface of the feeder 100.

The first claw portion 61 defines and functions as a guide to set the first claw portion 61 in the feeder 100.

The second claw portion 62, the third claw portion 63, and the fourth claw portion 64 engage with a second recessed portion 102 on the upper surface of the feeder 100.

The fifth claw portion 65 engages with a third recessed portion 103 on the upper surface of the feeder 100.

The fifth claw portion 65 is locked by a lock mechanism (not shown) provided on the feeder 100, such that the case 1 is fixed to the feeder 100.

The feeder 100 vibrates as described above to vibrate the case 1.

Vibration is applied to the feeder 100 by a vibrator (not shown).

Examples of the vibrator include a triaxial vibrator which applies three-dimensional vibrations in the longitudinal direction and the vertical direction to the feeder 100.

Due to the vibration, the electronic components M move down the first sloped surface 22a in the case body 10 and are transported forward on the first horizontal surface 21a.

Furthermore, in the transport section 40, the electronic components M move up on the second sloped surface 50a, are transported forward on the second horizontal surface 51a, and reach the discharge port 48.

In order to perform such transportation, different vibrations may be applied to the case body 10 and the transport section 40 by changing the frequency of vibrations or the like.

In this case, vibration to vibrate the transport section is applied to the first claw portion 61, the second claw portion 62, and the third claw portion 63 adjacent to the transport section and vibration to vibrate the case body 10 is applied to the fourth claw portion 64 and the fifth claw portion 65 adjacent to the case body 10.

In the case 1 configured as described above, a predetermined number of electronic components M are housed and stored in the housing space 11 of the case body 10 in a loose state, while the communication port 19 is closed by the shutter 30.

When the housed electronic components M are individually mounted on the mounting device, as shown in FIG. 1, the case 1 is set to the feeder 100, the shutter 30 is slid rearward using the slider 32, and the opening 31 of the shutter 30 coincides with the communication port 19 to open the communication port 19.

In this state, the feeder 100 is vibrated to vibrate the case 1.

When the case 1 vibrates, as shown in FIG. 4, the electronic components M are transported forward in the case body 10, pass through the communication port 19, and are transported to the discharge port 48 in the transport section 40.

The electronic components M having reached the discharge port 48 are picked up one by one by, for example, a vacuum chuck, a pick, or the like of the mounting device, and are continuously mounted in the mounting device.

In the housing space 11 of the case body 10, while the case 1 is set to the feeder 100, the electronic components M placed on the first horizontal surface 21a are sequentially transported to the communication port 19, pass through the communication port 19, and move to the second sloped surface 50a of the transport section 40.

The electronic components M on the first sloped surface 22a move down the first sloped surface 22a, are transported through the first horizontal surface 21a to the communication port 19, pass through the communication port 19, and move to the second sloped surface 50a of the transport section 40.

In the transport section 40, the electronic components M move up the second sloped surface 50a to the discharge port 48 on the second horizontal surface 51a.

After mounting all of the electronic components M in the case 1, the case 1 is detached from the feeder 100.

Here, the case 1 may be temporarily detached from the feeder 100 while all of the electronic components M in the case 1 are not mounted and some electronic components M remain in the case 1.

At this time, even if the electronic components M have passed through the communication port 19, since the electronic components M remain in the transport section 40, the state in which all of the remaining electronic components M remain housed in the case 1 is maintained.

Therefore, even if the case 1 is detached from the feeder 100, there is no possibility that any electronic component M remains on the feeder 100.

Therefore, even if the case 1 is set again to the feeder 100 and the remaining electronic components M are continuously supplied to the mounting device, the electronic components M to be newly supplied are not mixed with the electronic components M remaining on the feeder 100.

As a result, it is possible to continuously perform accurate mounting of the electronic components M.

Furthermore, there is no possibility of causing any failure in management of components.

With a case 1 according to a preferred embodiment of the present invention, the following advantageous effects are achieved.

(1) The case 1 according to the present preferred embodiment is directed to a case to be set to the feeder 100 to supply an electronic component M to a supply target, in which the case 1 includes the case body 10 including the housing space 11 that houses the plurality of electronic components M, the transport section 40 including the transport path 47 that is integrally joined to the case body 10 and transports the plurality of electronic components M to the supply target and the discharge port 48 that discharges the plurality of electronic components M from the transport path 47, and the communication port 19 that communicates the housing space 11 and the transport path 47 with each other and allows the plurality of electronic components M to move from the housing space 11 to the transport path 47.

With such a configuration, in the process of supplying the electronic components M from the case 1 to the mounting device of the component supply destination, it is possible to prevent the electronic components M in the case 1 and the electronic components M in the supply destination from being mixed.

(2) A case 1 according to a preferred embodiment may further include the shutter 30 that opens and closes the communication port 19.

With such a configuration, by closing the communication port 19 with the shutter 30, it is possible to reduce or prevent unintentional movement of the electronic components M toward the transport section 40, and to securely house and hold all of the electronic components M in the case body 10.

(3) In a case 1 according to a preferred embodiment, the case body 10 may include the first sloped surface 22a that is sloped at a downward gradient toward the communication port 19 to allow the plurality of electronic components M housed in the housing space 11 to reach the communication port 19.

With such a configuration, it is possible to smoothly and reliably transport the electronic components M to the communication port 19 in the case body 10.

(4) In a case 1 according to a preferred embodiment, the first sloped surface 22a is sloped at about 3° or more and about or less with respect to the horizontal direction when the case 1 is set to the feeder 100.

With such a configuration, it is possible to smoothly and reliably transport the electronic components M to the communication port 19 via the first sloped surface 22a.

(5) In a case 1 according to a preferred embodiment, the transport path 47 of the transport section 40 may include the second sloped surface 50a that is sloped at an upward gradient toward the supply target, and the feeder 100 allows the plurality of electronic components M to move up along the second sloped surface 50a by applying diagonally upward vibration to the second sloped surface 50a.

With such a configuration, it is possible to smoothly and reliably transport the electronic components M to the discharge port 48 in the transport section 40.

(6) In a case 1 according to a preferred embodiment, the second sloped surface 50a of the transport section 40 is preferably sloped at about 3° or more and about 10° or less with respect to the horizontal direction when the case 1 is set to the feeder 100.

With such a configuration, it is possible to smoothly and reliably transport the electronic components M to the discharge port 48 via the second sloped surface 50a.

Furthermore, the second sloped surface 50a may include irregularities on the surface.

When there are irregularities, it is easy to prevent the electronic components M from falling down the second sloped surface 50a, i.e., from flowing backwards.

Although preferred embodiments of the present invention have been described above, the present invention is not limited to the preferred embodiments, and modifications, improvements, and the like within the scope of the present invention are included in the present invention.

For example, instead of the configuration in which the electronic components M are supplied by vibration of the feeder 100, the electronic components M may be supplied to the supply target by simply transporting the electronic components M on the sloped surface.

The shape and the configuration of the transport section integrally joined to the case body are not limited as long as the transport section includes a transport path and a discharge port for transporting components to the supply target.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A case to be set to a feeder to supply a component to a supply target, the case comprising:
a case body including a housing space to house a plurality of components;
a transport section including a transport path integrally joined to the case body to transport the plurality of components to the supply target, and a discharge port to discharge the plurality of components from the transport path; and
a communication port to communicate the housing space and the transport path with each other and enable the plurality of components to move from the housing space to the transport path.

2. The case according to claim 1, further comprising a shutter to open and close the communication port.

3. The case according to claim 1, wherein the case body includes a first sloped surface with a downward gradient sloped toward the communication port to enable the plurality of components housed in the housing space to be transported to the communication port.

4. The case according to claim 3, wherein the first sloped surface is sloped at about 3° or more and about 15° or less with respect to a horizontal direction when the case is set to the feeder.

5. The case according to claim 1, wherein
the transport path includes a second sloped surface with an upward gradient sloped toward the supply target; and
the feeder enables the plurality of components to move up along the second sloped surface by applying vibration to the second sloped surface.

6. The case according to claim 5, wherein the second sloped surface is sloped at about 3° or more and about 10° or less with respect to the horizontal direction when the case is set to the feeder.

7. The case according to claim 1, wherein the case body has a flat box shape that has a larger dimension in a longitudinal direction than a dimension in a lateral direction orthogonal or substantially orthogonal to the longitudinal direction.

8. The case according to claim 1, wherein a materials of the case body has a resistivity of about 10E8 Ω/mm² to about 10E11 Ω/mm².

9. The case according to claim 2, wherein the shutter includes an elongated strip-shaped film.

10. The case according to claim 2, wherein the shutter is made of polyethylene terephthalate.

11. The case according to claim 2, wherein a width of the shutter is larger than a width of the communication port.

12. The case according to claim 2, wherein the shutter includes an opening with a same or substantially a same shape as the communication port.

13. The case according to claim 2, wherein the case body includes an upper guide above the communication port, and a curved guide below the communication port, and a bottom guide below the curved guide.

14. The case according to claim 13, wherein the shutter is slidably inserted across the upper guide, the curved guide, and the bottom guide.

15. The case according to claim 2, further comprising a slider including a plate piece to open and close the shutter is attached to a rear end of the shutter.
